(19) United States
(12) Patent Application Publication
(10) Pub. No.: US 2024/0363817 A1
(43) Pub. Date: Oct. 31, 2024

(54) SEMICONDUCTOR DEVICE AND MANUFACTURING METHOD THEREOF

(71) Applicant: EPISTAR CORPORATION, Hsinchu (TW)

(72) Inventors: Jia-Xing CHUNG, Hsinchu City (TW); Wei-Shan HU, Hsinchu City (TW); Ching-Tai CHENG, Hsinchu City (TW); Shih-An LIAO, Hsinchu City (TW)

(21) Appl. No.: 18/208,353

(22) Filed: Jun. 12, 2023

(30) Foreign Application Priority Data
Apr. 27, 2023 (TW) 112115762

(51) Int. Cl. H01L 33/62; H01L 33/38; H01L 33/40; H01S 5/042

(52) U.S. Cl. CPC H01L 33/62; H01L 33/38; H01L 33/40; H01S 5/04252; H01S 5/04254; H01L 33/20

(57) ABSTRACT

A semiconductor device includes a semiconductor stack, a protective layer on the semiconductor stack, an electrode on the semiconductor stack and electrically connected to the semiconductor stack, and a conductive bump on the electrode. The thickness of the conductive bump is measured from the topmost point of the conductive bump to the uppermost surface of the protective layer. The ratio of the thickness of the conductive bump to the maximum width of the conductive bump is between 0.1 and 0.4, and the electrode is devoid of gold.

### RELATED APPLICATION

This application claims the benefit of TW Application Serial No. 112115762, filed on Apr. 27, 2023, which is incorporated herein by reference in its entirety.

### BACKGROUND

### Technical Field

The present disclosure relates to a light-emitting device, and, in particular, to a light-emitting device with a conductive bump, and a manufacturing method thereof.

### Description of the Related Art

Light-emitting diodes (LEDs) have characteristics of low energy consumption, long lifetime, small volume, rapid response speed, stable optical output, and so on, and have been widely used in lighting and display fields.

As the continuous advancements in LED technology, the brightness of LED die is increasing continuously, and the size of LED die is also gradually being reduced, e.g., to less than 100 μm, 50 μm, or 30 μm. The use of LED dies is no longer limited to general lighting applications or as a backlight source in LCD monitors. Directly using LED dies as the pixels of an LED display could become a trend in next-generation displays.

### SUMMARY

An embodiment of the present disclosure provides a semiconductor device comprising a semiconductor stack; a protective layer on the semiconductor stack and having an uppermost surface; an electrode on the semiconductor stack and being electrically connected to the semiconductor stack; and a conductive bump on the electrode and having a convex outermost surface, a top, and a maximum width, wherein a thickness of the conductive bump is defined from the top to the uppermost surface, and a ratio of the thickness to the maximum width is from 0.1 to 0.4, and the electrode is devoid of gold (Au).

An embodiment of the present disclosure provides a semiconductor device, comprising a semiconductor stack; an electrode on the semiconductor stack and being electrically connected to the semiconductor stack; and a conductive bump on the electrode and having an outermost surface, a top, and a maximum width, wherein the conductive bump comprises Au, and a portion at the interface of the electrode and the conductive bump is devoid of Au.

### BRIEF DESCRIPTION OF THE DRAWINGS

FIG. 1A is a top view of a semiconductor device array in accordance with an embodiment of the present disclosure.

FIG. 1B is a cross-sectional view taken along line A-A′ of FIG. 1A.

FIG. 1C is a top view of a semiconductor device array in accordance with another embodiment of the present disclosure.

FIG. 1D is a cross-sectional view taken along line A-A′ of FIG. 1C.

FIG. 1E is a cross-sectional view of a semiconductor device array in accordance with another embodiment of the present disclosure.

FIG. 2A is a three-dimensional view of a semiconductor device in accordance with an embodiment of the present disclosure.

FIG. 2B is a cross-sectional view of a semiconductor device taken along line B-B′ of FIG. 2A.

FIG. 2C is a cross-sectional view of a semiconductor device in accordance with another embodiment of the present disclosure.

FIG. 2D is a three-dimensional view of a semiconductor device in accordance with another embodiment of the present disclosure.

FIG. 2E is a cross-sectional view of a semiconductor device taken along line B-B′ of FIG. 2D.

FIG. 3A is a top view of a semiconductor device in accordance with an embodiment of the present disclosure.

FIG. 3B is a cross-sectional view of a semiconductor device taken along line C-C′ of FIG. 3A.

FIG. 3C is a cross-sectional view of a semiconductor device taken along line D-D′ of FIG. 3A.

FIG. 4A is a cross-sectional view of a semiconductor device array in accordance with an embodiment of the present disclosure.

FIG. 4B is a cross-sectional view of a semiconductor device array of FIG. 4A after removing one semiconductor device.

FIG. 4C is a top view of a semiconductor device array of FIG. 4A after removing one semiconductor device.

FIG. 4D is a cross-sectional view of a semiconductor device array in accordance with another embodiment of the present disclosure.

FIG. 4E is a cross-sectional view of a semiconductor device array in accordance with another embodiment of the present disclosure.

FIGS. 5A-5D are schematic views of various stages for transferring semiconductor devices in accordance with an embodiment of the present disclosure.

FIGS. 6A-6C are schematic views of various stages for transferring semiconductor devices in accordance with another embodiment of the present disclosure.

FIGS. 7A-7D are schematic views of various stages in a method of manufacturing semiconductor devices in accordance with an embodiment of the present disclosure.

FIGS. 8A-8D are schematic views of various stages in a method of manufacturing semiconductor devices in accordance with another embodiment of the present disclosure.

FIG. 9A is a three-dimensional view of a semiconductor device in accordance with another embodiment of the present disclosure.

FIG. 9B is a cross-sectional view of a semiconductor device taken along line B-B′ of FIG. 9A.

FIG. 10A is a schematic view of a semiconductor device fixed on the target substrate in accordance with an embodiment of the present disclosure.

FIG. 10B is a schematic view of a semiconductor device fixed on the target substrate in accordance with another embodiment of the present disclosure.

### DETAILED DESCRIPTION OF THE INVENTION

The following embodiments will be described with accompanying figures to illustrate the concept of the present disclosure. In the drawings or the specification, same symbols will be used for the same or similar parts, and the shape, thickness or height of an element in the drawings may be enlarged or reduced within a reasonable scope. Various embodiments exemplified in the present disclosure are merely used for illustrating the present disclosure, instead of limiting the scope of the present disclosure. Any obvious modifications or alterations done to the present disclosure will not depart from the spirit and scope of the present disclosure.

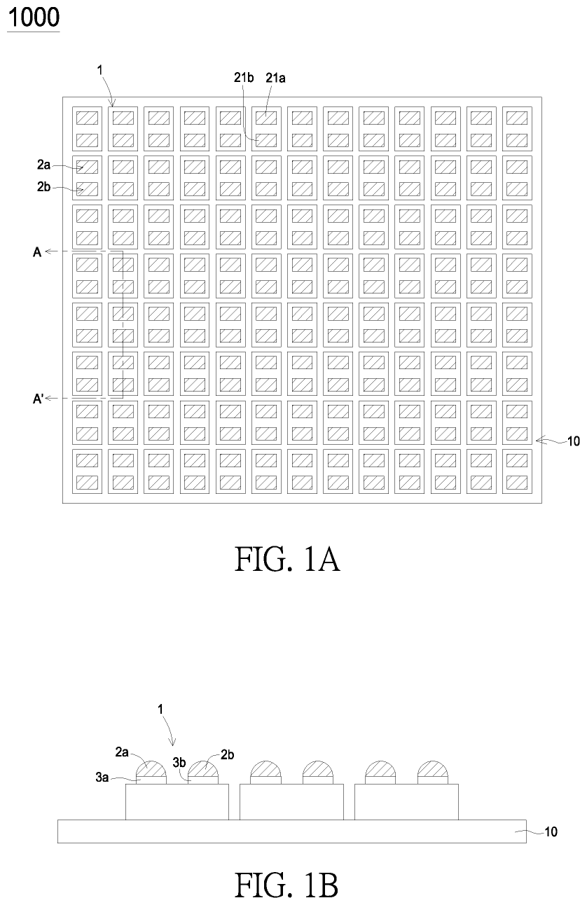

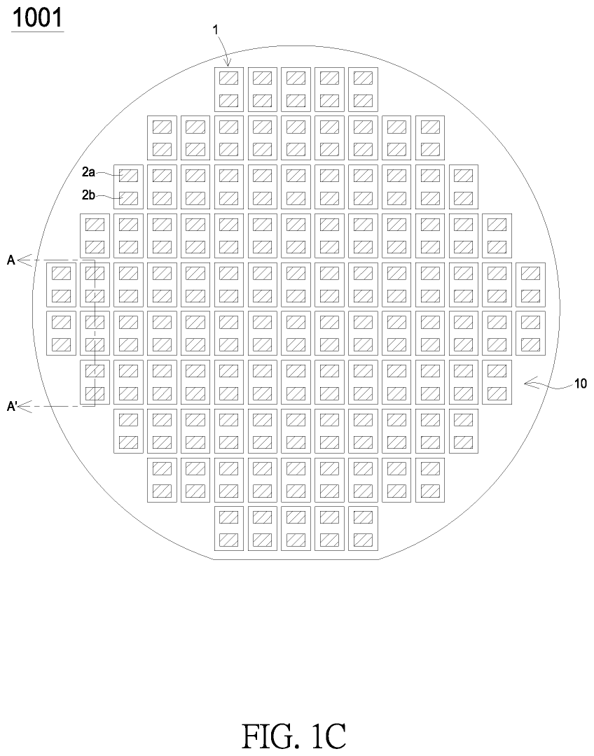

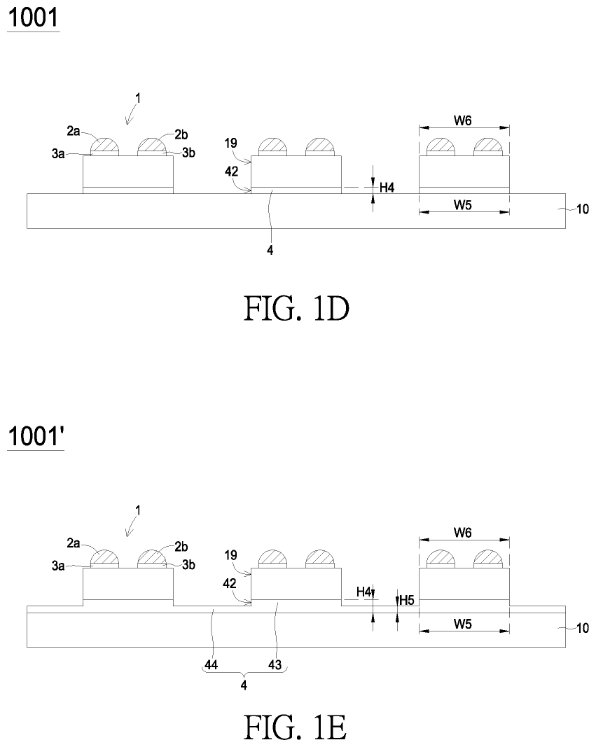

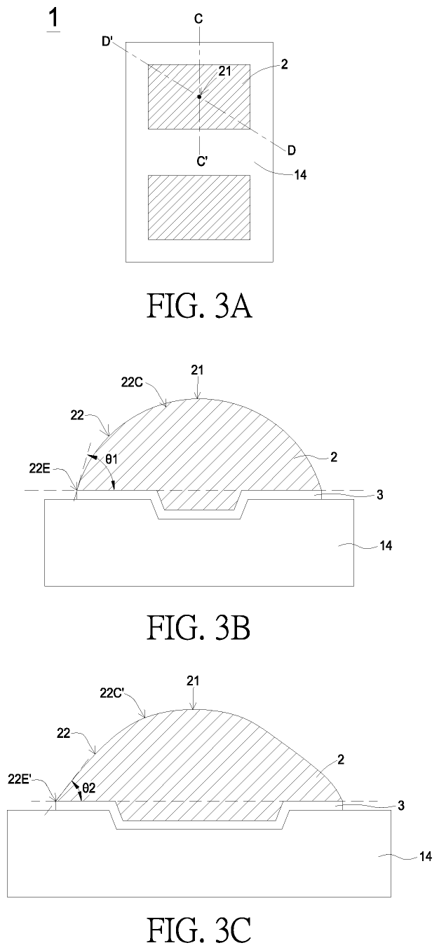

FIG. 1A is a top view of a semiconductor device array 1000 in accordance with an embodiment of the present disclosure. The semiconductor device array 1000 includes a plurality of semiconductor devices 1 arranged in an array on a substrate 10. The semiconductor device 1 may be a light-emitting diode (LED), laser diode (LD), or transistor. The semiconductor device array 1000 may be composed of a single type or various types of semiconductor device 1. The substrate 10 can be a growth substrate of the semiconductor device or can be a carrier when the growth substrate is removed. The material of the substrate 10 includes but is not limited to: germanium (Ge), gallium arsenide (GaAs), indium phosphide (InP), sapphire, silicon carbide (SiC), silicon (Si), lithium aluminate (LiAlO₂), zinc oxide (ZnO), gallium nitride (GaN), aluminum nitride (AlN), metal, glass, thermal release tape, UV release tape, chemical release tape, heat resistant tape, blue tape, or tapes with dielectric release layer. Each of the semiconductor devices 1 has a pair of conductive bumps 2a, 2b for electrically or physically connecting to the external circuit (e.g., circuit board, backplane) on the side away from the substrate 10. The projected shape of the conductive bump is substantially rectangular in the top view, as shown in FIGS. 1A and 3A

FIG. 1B is a cross-sectional view taken along line A-A′ of FIG. 1A. The semiconductor device 1 has a pair of electrodes 3a, 3b on the side away from the substrate 10. The conductive bumps 2a, 2b are directly disposed on the electrode 3a, 3b, respectively. The upper surfaces of the conductive bumps 2a, 2b are of arc shape and not parallel to the upper surfaces of the electrodes 3a, 3b.

In one embodiment, the material of the conductive bumps 2a, 2b is different from the material of the electrodes 3a, 3b. The material of the electrodes 3a, 3b includes, such as gold (Au), silver (Ag), copper (Cu), chromium (Cr), aluminum (Al), platinum (Pt), nickel (Ni), titanium (Ti), alloys thereof, or combinations of the stacking layers thereof. The material of the conductive bumps 2a, 2b may include a low melting point metal or a low liquidus melting point alloy, whose melting point or liquidus temperature is lower than 210° C., such as bismuth (Bi), tin (Sn), indium (In), or alloys thereof. In an embodiment, the melting point of the low melting point metal or the liquidus temperature of the low liquidus melting point alloy is lower than 170° C. The material of the low liquidus melting point alloy may be tin-indium alloy or tin-bismuth alloy.

FIG. 1C is a top view of a semiconductor device array 1001 in accordance with another embodiment of the present disclosure. The semiconductor device array 1001 includes a plurality of semiconductor devices 1 arranged in a predetermined pattern on the substrate 10. The substrate 10 has a substantially circular shape. For the material of the substrate 10, reference can be made to the aforementioned relevant paragraphs. FIG. 1D is a cross-sectional view taken along line A-A′ of FIG. 1C. An adhesive structure 4 is between each semiconductor device 1 and the substrate 10. Each of the plurality of semiconductor devices 1 is temporally fixed on the substrate 10 by the adhesive structure 4. Each of the plurality of semiconductor devices 1 has a pair of the electrodes 3a, 3b on the side away from the substrate 10. The conductive bumps 2a, 2b are directly disposed on the electrodes 3a, 3b, respectively. The upper surfaces of the conductive bumps 2a, 2b are of arc shape from the lateral view and not completely parallel to the upper surfaces of the electrodes 3a, 3b. The adhesive structure 4 may include polymer, such as polyimide or benzocyclobutane (BCB). For the material of the conductive bumps 2a, 2b and the material of the electrodes 3a, 3b, reference can be made to the aforementioned relevant paragraphs. As shown in FIG. 1D, for each semiconductor device 1, an outer side 42 of the adhesive structure 4 is substantially co-planar with an outermost side 19 of the semiconductor device 1. The adhesive portion 4 has a thickness H4, which is about 2-3 μm or 1-10 μm. In another embodiment, for each of the semiconductor devices 1, the outer side 42 is not co-planar with the outermost side 19 of the semiconductor device 1, and the adhesive structure 4 can be retracted or protruded relative to the outermost side 19 of the semiconductor device 1. The adhesive structure 4 has a maximum width W5 and the semiconductor device 1 has a maximum width W6, and the maximum width W5 is substantially equal to the maximum width W6. In another embodiment, the maximum width W5 can be less than or more than the maximum width W6.

FIG. 1E is a cross-sectional view of the semiconductor device array 1001′ in accordance with another embodiment of the present disclosure. The semiconductor device array 1001′ includes a plurality of semiconductor devices 1 arranged in a predetermined pattern on a substrate 10. For the material of the substrate 10, reference can be made to the aforementioned relevant paragraphs. An adhesive structure 4 is between the plurality of semiconductor devices 1 and the substrate 10. The plurality of semiconductor devices 1 is temporarily fixed on the substrate 10 by the adhesive structure 4. Each semiconductor device 1 has a pair of the electrodes 3a, 3b on the side away from the substrate 10. The conductive bumps 2a, 2b are directly disposed on the electrodes 3a, 3b, respectively. For the material of the adhesive structure 4, the structure and material of the conductive bumps 2a, 2b, and the structure and material of the electrodes 3a, 3b, references can be made to the aforementioned relevant paragraphs. As shown in FIG. 1E, the adhesive structure 4 has mesa portions 43 and continuous portions 44. The continuous portions 44 are uninterrupted and continuously disposed on the substrate 10 across the areas below the plurality of semiconductor devices 1 and between two adjacent semiconductor devices 1. Each of the mesa portions 43 is between each of the semiconductor devices 1 and the continuous portions 44, protruding from the continuous portion 44 and corresponding to one of the plurality of semiconductor devices 1. For each of the plurality of semiconductor devices 1, the outer side 42 of the mesa portion 43 is co-planar with or near the outermost side 19 of the semiconductor device 1. The adhesive portion 4 has a thickness H4, which is about 2-3 μm. The continuous portion 44 has a thickness H5, which is more than 0 μm and less than 1 μm. In another embodiment, for each semiconductor device 1, the outer side 42 is not co-planar with the outermost side 19 of the semiconductor device 1, and the mesa portion 43 can be retracted or protruded relative to the outermost side 19 of the semiconductor device 1. The mesa portion 43 has a maximum width W5 and the semiconductor device 1 has a maximum width W6, and the maximum width W5 is substantially equal to the maximum width W6. In another embodiment, the maximum width W5 may be less than or more than the maximum width W6.

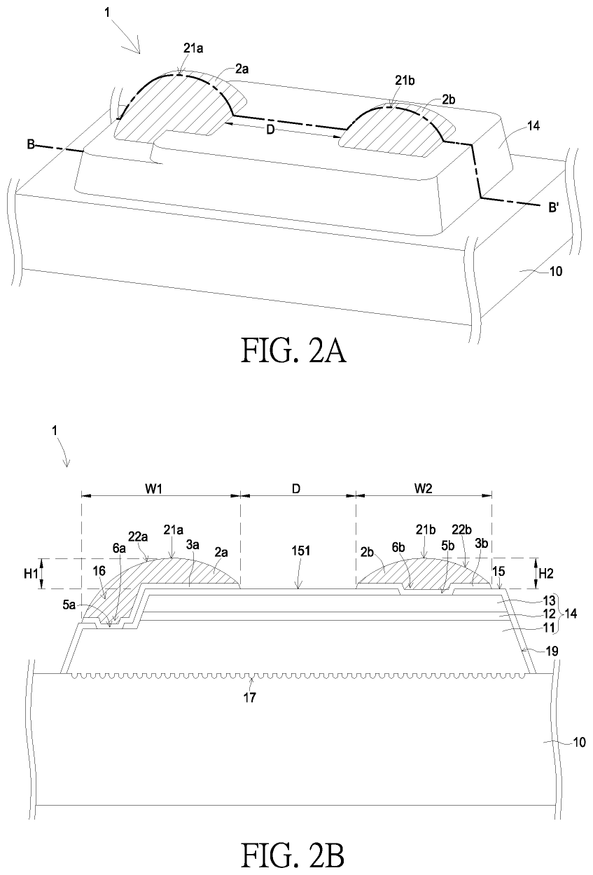

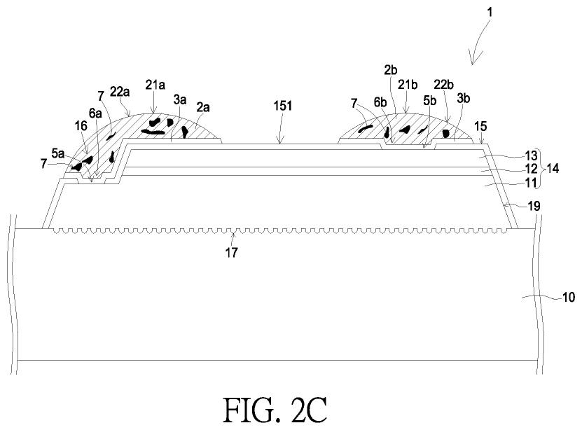

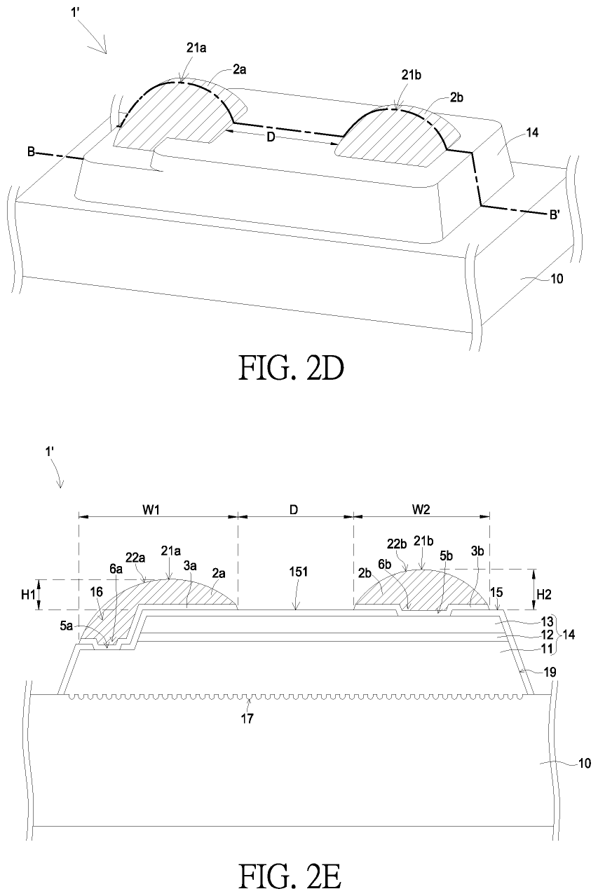

FIG. 2A is a three-dimensional view of a semiconductor device 1 on a substrate 10 in accordance with an embodiment of the present disclosure. The maximum side length of the semiconductor device 1 is not more than 100 μm or 50 μm. For example, the maximum side length of the semiconductor device is about 40 μm and the width thereof is about 20 μm. The conductive bump 2a and the conductive bump 2b have opposite polarities (positive, negative), and the minimal horizontal distance D therebetween is less than 40 μm. For example, the maximum side length of the semiconductor device 1 is about 40 μm and the distance D thereof is about 15 μm. The conductive bumps 2a, 2b completely cover the electrode (such as the electrodes 3a, 3b in FIG. 1B) and have convex arc shapes and tops 21a, 21b. Referring to FIG. 1A, the tops 21a, 21b are located approximately at the geometric center of the conductive bumps 2a, 2b and/or the electrodes.

FIG. 2B is a cross-sectional view of a semiconductor device 1 taken along line B-B′ of FIG. 2A. The semiconductor device 1 is placed on the substrate 10, and has a semiconductor stack 14, a protective layer 15, a first electrode 3a, a second electrode 3b, a first conductive bump 2a, and a second conductive bump 2b. The outermost side 19 of the semiconductor stack 14 is an inclined plane, which is inclined with respect to the substrate 10. The semiconductor stack 14 includes a first semiconductor layer 11, an active layer 12, and a second semiconductor layer 13. The first semiconductor layer 11 and the second semiconductor layer 13 can respectively provide electrons and holes so that the electrons and holes can recombine in the active layer 12 to emit light. The first semiconductor layer 11, the active layer 12 and the second semiconductor layer 13 may include III-V semiconductor material, such as AlₓIn_{y}Ga_{(1-x-y)}N or AlₓIn_{y}Ga_{(1-x-y)}P, wherein 0≤x, y≤1; (x+y)≤1. Depending on the material of the semiconductor stack 14, the active layer 12 can emit a red light with a peak wavelength in a range of 610 nm and 650 nm, a green light with a peak wavelength in a range of 530 nm and 570 nm, a cyan light with a peak wavelength in a range of 500 nm and 485 nm, a blue light with a peak between 450 nm and 490 nm, a violet light with a peak wavelength in a range of 400 nm and 450 nm, or an ultraviolet light with a peak wavelength in a range of 280 nm and 400 nm. The maximum thickness of the semiconductor stack 14 is about equal to or less than 10 μm. In an embodiment, the lower surface 17 of the first semiconductor layer 11 is a rough surface and in contact with the substrate 10. In another embodiment, the lower surface 17 of the first semiconductor layer 11 is a substantially flat surface (not shown). In another embodiment, the substrate 10 is a growth substrate for epitaxial growth of the semiconductor stack 14 and can be a patterned sapphire substrate (PSS) so the entire upper surface of the substrate 10 facing the semiconductor stack 14 is a rough surface (not shown). In an embodiment, the semiconductor device 1 includes a carrier (not shown) under the semiconductor stack 14 to support the semiconductor stack 14, and the carrier may be an epitaxial growth substrate of the semiconductor stack 14 or not an epitaxial growth substrate. For the material of the carrier, reference can be made to the aforementioned relevant paragraphs of the substrate 10, but the selection of materials should conform to the theoretical and practical feasibility.

The semiconductor stack 14 has a mesa 16 which is formed by removing a portion of the active layer 12 and the second semiconductor layer 13 to expose the first semiconductor layer 11. The protective layer 15 covers the upper surface of the second semiconductor layer 13, sidewalls of the first semiconductor layer 11, sidewalls of the active layer 12, sidewalls of the second semiconductor layer 13, and the upper surface of the first semiconductor layer 11 in the mesa 16. The protective layer 15 can directly contact the substrate 10. In another embodiment, the protective layer 15 is not in contact with the substrate 10. The protective layer 15 has a first opening 5a in the mesa 16 to expose portions of the first semiconductor stack 11. The protective layer 15 has a second opening 5b on the second semiconductor layer 13 to expose portions of the second semiconductor layer 13. The first electrode 3a is in the mesa 16, wherein the first electrode 3a has a portion formed on the protective layer 15 and covers the protective layer 15 in and outside of the mesa 16. The first electrode 3a has a first recess 6a formed in the first opening 5a and is electrically connected to the first semiconductor layer 11. The first electrode 3a has a stepped shape at the position of the mesa 16. The second electrode 3b has a portion on the protective layer 15 outside the second opening 5b and a second recess 6b formed in the second opening 5b for being electrically connected to the second semiconductor layer 13.

The protective layer 15 may be a single-layer or multi-layers structure and has a property of electrical insulation. The material of the single-layer structure may include oxide, nitride, or polymer. The oxide may include aluminum oxide (Al₂O₃), silicon oxide (SiO₂), titanium oxide (TiO₂), tantalum pentoxide (Ta₂O₅), or aluminum oxide (AlOₓ). The nitride may include aluminum nitride (AlN) or silicon nitride (SiNₓ). The polymer may include polyimide or benzocyclobutane (BCB). The material of the multi-layers structure may include aluminum oxide (Al₂O₃), silicon oxide (SiO₂), titanium oxide (TiO₂), niobium pentoxide (Nb₂O₅), silicon nitride (SiNₓ), or combinations thereof. The multi-layers structure can also form a distributed Bragg reflector (DBR).

Referring to FIG. 2B, a first conductive bump 2a is directly formed over the first electrode 3a. The first conductive bump 2a may completely or partially fill the first recess 6a of the first electrode 3a, and the outermost surface 22a of the first conductive bump 2a has a macroscopically smooth and convex arc shape. The first conductive bump 2a has a top 21a, which is a region having farthest distance between the first conductive bump 2a and the substrate 10. As shown in FIG. 2B, the outermost surface 22a of the first conductive bump 2a is not parallel to the lowest surface of the first conductive bump 2a, and is not parallel to the upper surface of the first electrode 3a, either. The lower surface 17 of the first semiconductor layer 11 is a rough surface, wherein the roughness of the outermost surface 22a of the first conductive bump 2a is less than the roughness of the lower surface 17 of the first semiconductor layer 11 and is less than the roughness of the upper surface of the first electrode 3a.

Referring to FIG. 2B, a second conductive bump 2b directly covers the second electrode 3b. The second conductive bump 2b may completely or partially fill the second recess 6b of the second electrode 3b, and the outermost surface 22b of the second conductive bump 2b has a macroscopically smooth and convex arc shape. The second conductive bump 2b has a top 21b, which is a region of the second conductive bump 2b farthest away from the substrate 10. As shown in the FIG. 2B, the outermost surface 22b of the second conductive bump 2b is not parallel to the lowest surface of the second conductive bump 2b, and is not parallel to the upper surface of the second electrode 3b, either. The roughness of the outermost surface 22b of the second conductive bump 2a is less than the roughness of the lower surface 17 of the first semiconductor layer 11 and is less than the roughness of the upper surface of the second electrode 3b. Preferably, the top 21a of the first conductive bump 2a and the top 21b of the second conductive bump 2b are substantially in a same level height, which is beneficial for the device 1 to be stably affixed on the substrate subsequently. However, in practice, there may be a certain degree of high difference under the tolerance of the fabrication process. Generally, the lowest surface of the first conductive bump 2a and the second conductive bump 2b are formed conformally on the first electrode 3a and the second electrode 3b, respectively, whereas their lowest points are not commonly in the same level height. As shown in FIG. 2B, a first thickness H1 can be obtained by measuring the vertical distance from the top 21a of the first conductive bump 2a to the uppermost surface 151 of the protective layer 15. The first conductive bump 2a has a first (maximum) width W1, wherein the ratio H1/W1 is between 0.1˜0.4, preferably between 0.1˜0.25. A second thickness H2 can be obtained by measuring the vertical distance from the top 21b of the second conductive bump 2n to the uppermost surface 151 of the protective layer 15. The second conductive bump 2b has a second (maximum) width W2, wherein the ratio H2/W2 is between 0.1˜0.4, preferably between 0.1˜0.25. The ratios of H1/W1 and H2/W2 may be the same or different. The second thickness H2 of the second conductive bump 2b is between 4˜6 μm.

If the first conductive bump 2a is more densely filled in the first recess 6a of the first electrode 3a and/or the second conductive bump 2b is more densely filled in the second recess 6b of the second electrode 3b, the reliability of the physical or electrical connection between the semiconductor device 1 and the circuit substrate (not shown) can be improved, and the probability of open circuit between the semiconductor device 1 and the circuit substrate can be reduced. Specifically, if the structure of the semiconductor device 1 is as shown in FIG. 2B but does not have the conductive bump 2a/2b, when the semiconductor device 1 is fixed to a circuit substrate by a solder, the solder between the first electrode 3a and the circuit substrate (not shown) may sometimes have holes near the first recess 6a, and the solder between the second electrode 3b and the circuit substrate (not shown) also may sometimes have holes near the second recess 6b. These holes may decrease the fixing strength between the semiconductor device 1 and the circuit substrate.

If a thermal treatment step is present during the formation of the conductive bump, under a specific combination of the selected materials of the conductive bump and the electrode, discretely distributed metal particles may be formed within the conductive bump after the thermal treatment step, as shown in FIG. 2C. FIG. 2C is a cross-sectional view of a semiconductor device 1 in accordance with another embodiment of the present disclosure. For the structure shown in FIG. 2C, reference can be made to FIG. 2B and the aforementioned relevant paragraphs. The first conductive bump 2a and the second conductive bump 2b have discretely distributed, irregularly sized and irregularly shaped particles 7 distributed therein. The material of the particles 7 is different from the material of the conductive bump 2a, 2b, but is partially the same as the material of the electrode 3a, 3b, such as gold, platinum, and alloy thereof. The shape of particles 7 may be bar shape, polygon, leaf shape, or teardrop shape.

FIGS. 2D-2E are schematic views of a semiconductor device 1′ in accordance with another embodiment of the present disclosure. For the structure of FIGS. 2D-2E, reference can be made to FIGS. 2A-2B and the aforementioned relevant paragraphs. As shown in FIG. 2D, the conductive bumps 2a, 2b have convex arc shapes and tops 21a, 21b. The top 21a and top 21b are not in the same level height. The top 21a is slightly lower than the top 21b. FIG. 2E is a cross-sectional view of a semiconductor device 1′ taken along line B-B′ of FIG. 2D. The conductive bump 2a is above the mesa 16. When the volume of the conductive bump 2a is similar to that of the conductive bump 2b, because a portion of the conductive bump 2a fills the mesa 16, the top 21a of the conductive bump 2a is slightly lower than the top 21b of the conductive bump 2b. In an embodiment, the first thickness H1 of the first conductive bump 2a is 0.4 to 1 μm less than the second thickness H2 of the second conductive bump 2b. In another embodiment, the first thickness H1 of the first conductive bump 2a is the same as or larger than the second thickness H2 of the second conductive bump 2b.

FIG. 3A is a top view of a semiconductor device 1 in accordance to an embodiment of the present disclosure. FIG. 3B is a cross-sectional view of a semiconductor device 1 taken along line C-C′ of FIG. 3A. FIG. 3C is a cross-sectional view of a semiconductor device 1 taken along line D-D′ of FIG. 3A. The semiconductor device 1 includes a semiconductor stack 14 and an electrode 3 as well as a conductive bump 2 on the semiconductor stack 14. The projected shape of the conductive bump 2 and the electrode 3 in FIG. 3A is substantially a rectangle. The outermost surface 22 of the conductive bump 2 has a macroscopically smooth and convex arc shape in the cross-sectional view. As shown in FIG. 3B, a cross-sectional view of the outermost surface 22 is a curve 22C, and the curve 22C has an endpoint 22E in contact with the upper surface of the electrode 3, and a tangent line of the curve 22C at the endpoint 22E form an angle θ1 with respect to the upper surface of the electrode 3. The angle θ1 is 70°<θ1<90°. As shown in FIG. 3C, another cross-sectional view of the outermost surface 22 is a curve 22C′, and the curve 22C′ has an endpoint 22E′ in contact with the upper surface of the electrode 3, and a tangent line of the curve 22C′ at the endpoint 22E′ form an angle θ2 with respect to the upper surface of the electrode 3. Angle θ2 is smaller than angle θ1 and is preferably 30°<θ2<70°. In other words, as shown in FIG. 3A, the cross-sectional shape of the conductive bump 2 in a direction that is parallel to the side length of the electrode is not equal to a cross-sectional shape of the conductive bump in a direction of a diagonal line D-D′ of the electrode 3.

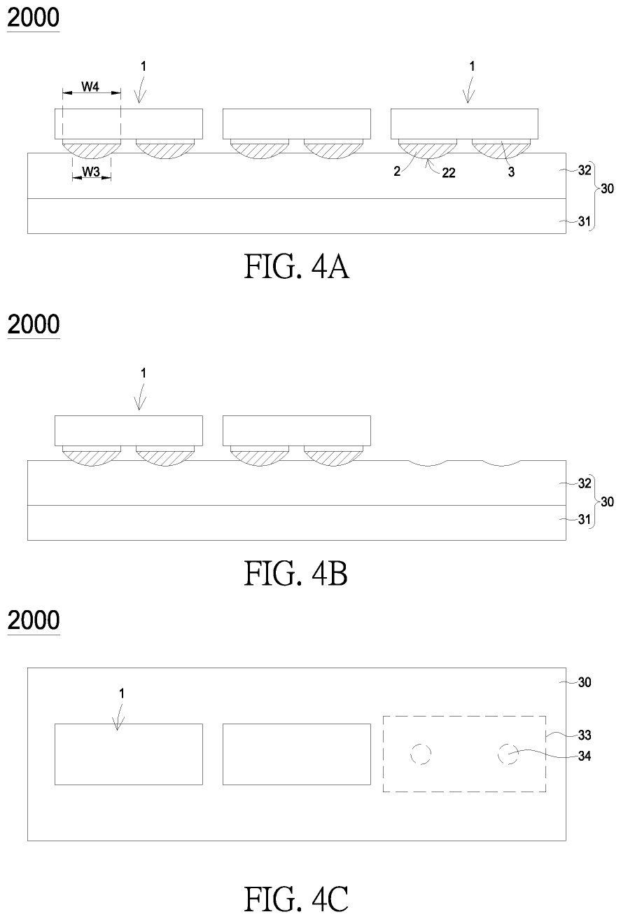

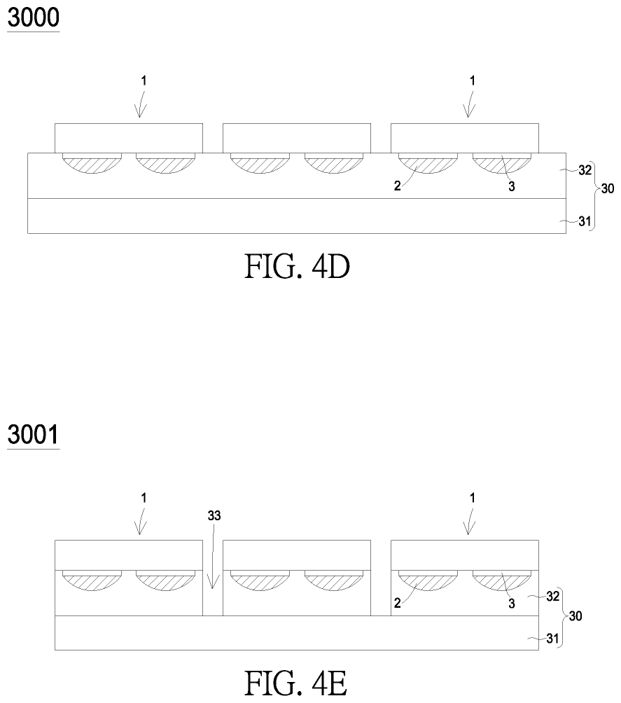

FIG. 4A shows a semiconductor device array 2000 in accordance with an embodiment of the present disclosure. The semiconductor device array 2000 includes a plurality of semiconductor devices 1 and a carrier 30. For simplicity, only three of the semiconductor devices 1 in one dimension are shown in FIG. 4A, but the semiconductor device array 2000 may include m*n numbers of the semiconductor devices 1, wherein m, n are integers greater than or equal to 0, and m and n are not 0 at the same time. The semiconductor devices 1 are disposed on the carrier 30 in a way that the conductive bumps 2 facing the carrier 30 (or called “flip-chip”). The carrier 30 may support and fix the semiconductor device 1. The carrier 30 includes a carrier plate 31 and an adhesion layer 32, wherein the material of the carrier plate 31 may be a light-transmitting material that can be transmitted by a light with a specific wavelength emitted by the LED or laser diode (LD), such as glass, sapphire, or polymer material. The adhesion layer 32 may include a thermal release tape, UV release tape, chemical release tape, heat resistant tape, blue tape, or tapes with dielectric release layer. In another embodiment, the adhesion layer 32 may also include a polymer, such as a polyimide and benzocyclobutane (BCB). When the semiconductor devices 1 are arranged on the carrier 30 in the direction of “flip chip”, the smooth and convex outermost surfaces 22 of the conductive bumps 2 are in direct contact with the adhesion layer 32. As shown in the FIG. 4A, the conductive bumps 2 may be partially embedded in the adhesion layer 32. The embedded portion of each of the conductive bumps 2 has a maximum width W3 parallel to the surface of the adhesion layer 32, and the conductive bump 2 has a maximum width W4, wherein W4>W3. Besides, the outermost surface 22 of each of the conductive bumps 2 is smooth and arc-shaped, and, in a selected projection direction, the projected area of the portion of each of the conductive bumps 2 embedded in the adhesion layer (such as the area of the indentation 34 in FIG. 4C) is less than the area of the electrode 3 and has a lower adhesive force, which is beneficial for the subsequent transferring process for transferring the semiconductor devices 1 from the carrier 30 to another location. The transferring process of the semiconductor devices 1 will be described in the paragraphs below.

FIGS. 4B and 4C show a side view and a top view of a semiconductor device array 2000 of FIG. 4A after removing one semiconductor device 1. Referring to FIG. 4C, in the top view, the upper surface of the carrier 30 can define a removal area 33 (as in dotted line), representing an exposed region on the carrier 30 after removing a semiconductor device 1. An indentation 34 is included in the removal area 33. The indentation 34 is a region, which is pressed by the conductive bump 2, of the adhesion layer 32, and the indentation 34 has a projected area in the top view. According to the experimental results, when the ratio of the projected area of the indentation 34 to the projected area of the semiconductor device 1 is less than 0.2, it is easier to pick up the semiconductor device 1 from the carrier 30 and move it to another location.

FIGS. 4D-4E show a semiconductor device array in accordance with another embodiment of the present disclosure. FIG. 4D shows a semiconductor device array 3000. For the semiconductor device array 3000, reference can be made to FIG. 4A and the aforementioned relevant paragraphs. The semiconductor device array 3000 includes a plurality of semiconductor devices 1 and a carrier 30. The carrier 30 includes a carrier plate 31 and an adhesion layer 32. The plurality of semiconductor devices 1 is disposed on the carrier 30 in a way that the conductive bumps 2 facing the carrier 30. The conductive bumps 2 and the electrodes 3 are completely embedded in the adhesion layer 32 and are completely wrapped by the adhesion layer 32. The adhesion layer 32 covers the lower surface of the semiconductor device 1 which is not covered by the electrode 3. By being temporarily fixed onto the adhesive layer 32, the positions of the semiconductor devices 1 on the carrier 30 can be maintained and are not easy to be changed during the subsequent processes. FIG. 4E shows a semiconductor device array 3001. For the semiconductor device array 3001, reference can be made to FIG. 4D and the aforementioned relevant paragraphs. The semiconductor device array 3001 includes a plurality of semiconductor devices 1 and a carrier 30. The carrier 30 includes a carrier plate 31 and a plurality of adhesion layers 32 separated from each other, and the horizontal position and width of an adhesion layer 32 are corresponded to a semiconductor device 1. An aisle 33 with a width greater than 0 is between two adjacent adhesion layers 32. The plurality of semiconductor devices 1 is disposed on the carrier 30 in such a way that the conductive bump 2 facing the carrier 30. The conductive bump 2 and the electrode 3 are completely embedded in the adhesion layer 32 and are completely wrapped by the adhesion layer 32. The adhesion layer 32 covers the lower surface of the semiconductor device 1 which is not covered by the electrode 3.

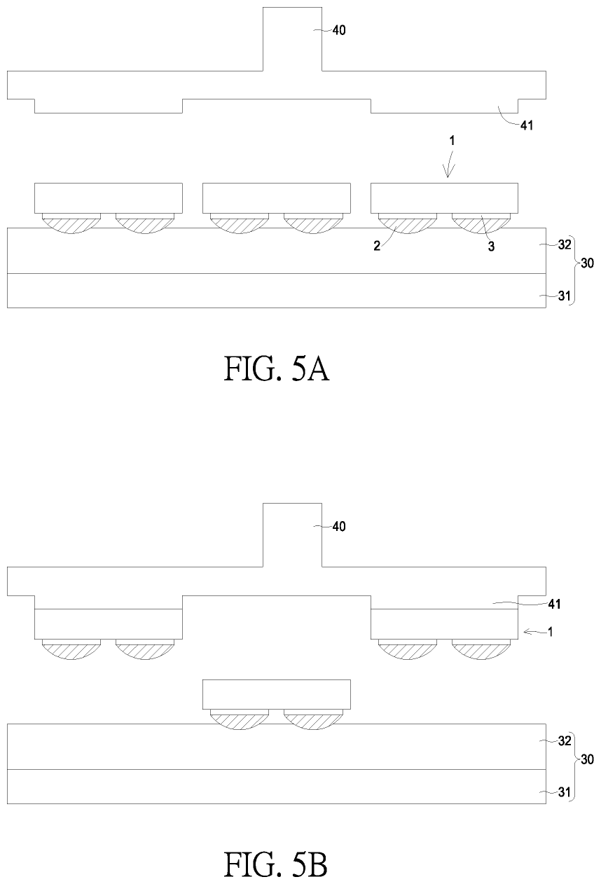

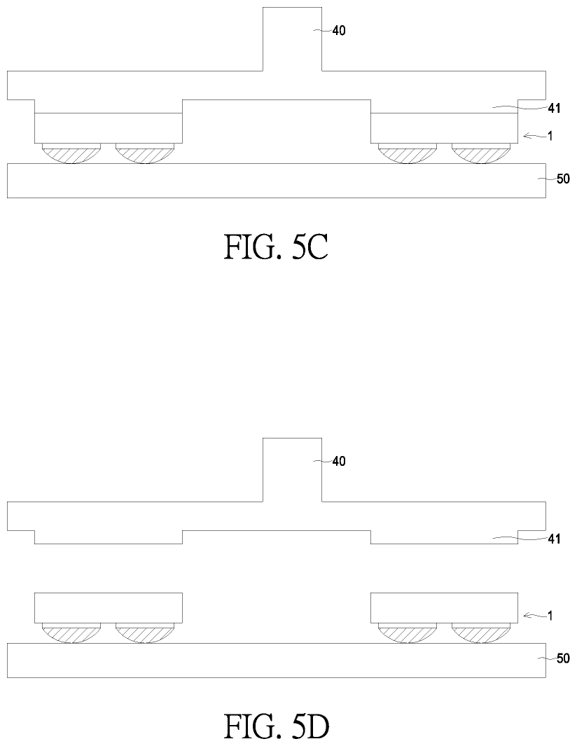

FIGS. 5A-5D show a step for transferring the semiconductor device 1, in accordance with an embodiment of the present disclosure. As shown in FIG. 5A, a plurality of semiconductor devices 1 is arranged in an array on the carrier 30. The plurality of semiconductor devices 1 is in contact with the adhesion layer 32 of the carrier 30 by portions of the surfaces of the conductive bumps so the plurality of semiconductor device 1 can be temporarily fixed onto the carrier 30. A pick-up tool 40 is provided to transfer the semiconductor device 1 from the carrier 30 to another location. The pick-up tool 40 has a plurality of grabbing portions 41, and each of the grabbing portions 41 is corresponded to the position of the semiconductor device 1 which is ready to be picked up. As shown in FIG. 5B, the pick-up tool 40 moves close to the plurality of semiconductor devices 1. After the grabbing portions 41 contacts some of the plurality of semiconductor devices 1, the pick-up tool moves upward so that the semiconductor devices 1 grabbed by the grabbing portions 41 leave the carrier 30. Notably, during the pick-up step, the adhesion between the grabbing portion 41 and the semiconductor device 1 should be greater than the adhesion between the semiconductor device 1 and the carrier 30. The semiconductor devices 1, which are not contacted by the grabbing portions 41, stay on the carrier 30. As shown in FIG. 5C, the pick-up tool 40 moves to a position above a predetermined place of the target substrate 50 together with the semiconductor devices 1 temporarily fixed on the grabbing portions 41. At this predetermined place, the semiconductor devices 1 may directly or indirectly contact the target substrate 50, and eventually be directly placed or fixed on the target substrate 50. As shown in FIG. 5D, the semiconductor devices 1 leave the pick-up tool 40 and stay on the target substrate 50, while the pick-up tool 40 may move to the same or a different carrier 30 to grab other semiconductor devices 1. The transferred semiconductor devices 1 are disposed on the substrate 50 in such a way that the conductive bumps 2 face the target substrate 50. The target substrate 50 may be a circuit board of a display, a thin-film transistor (TFT) substrate, a substrate having a redistribution layer (RDL), or a sub-mount substrate of a package. In another embodiment, the target substrate 50 may be a temporary carrier similar to the carrier 30. In FIGS. 5A-5D, the connection mode of the semiconductor device 1 and the carrier 30 is not limited to the form shown in FIG. 4A, and may be the forms shown in FIGS. 4D and 4E.

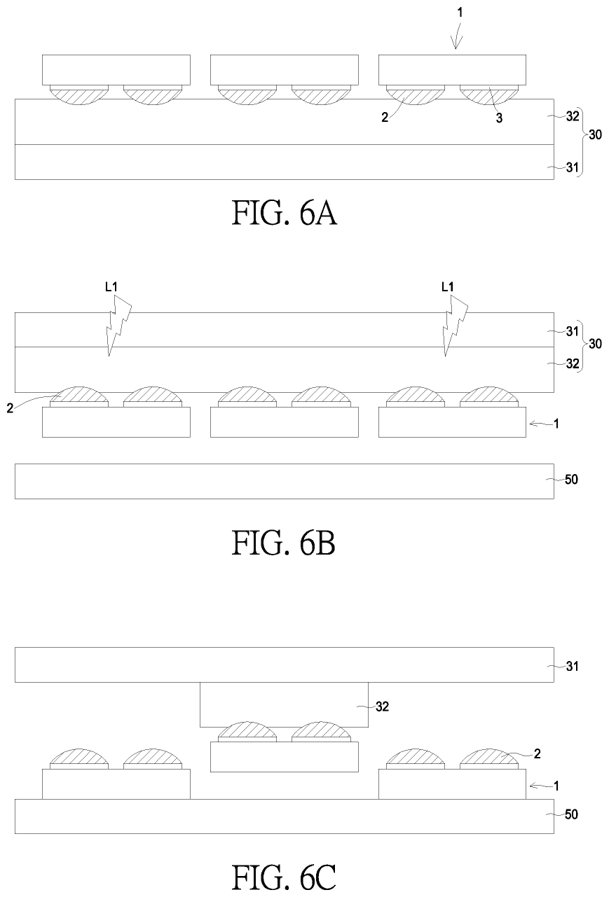

FIGS. 6A-6C are schematic views of a step for transferring the semiconductor device 1 in accordance with another embodiment of the present disclosure. FIG. 6A shows a plurality of semiconductor devices 1 disposed in an array on the carrier 30. Each semiconductor device 1 is in contact with the adhesion layer 32 of the carrier 30 by a portion of the surface of the conductive bumps 2 so the plurality of semiconductor devices 1 can be temporarily fixed onto the carrier 30. Then, the structure of FIG. 6A is flipped over or the target substrate 50 is moved, and such that the plurality of semiconductor devices 1 can be located between the carrier 30 and the target substrate 50 wherein the plurality of semiconductor devices 1 does not directly contact the target substrate 50. For example, as shown in FIG. 6B, the semiconductor device 1 is suspended over the target substrate 50. A laser energy L1 is provided to irradiate a specific place of the adhesion layer 32 from the side of the carrier plate 31, wherein the specific place corresponds to one of the semiconductor devices 1 which is ready to be transferred. The laser energy L1 may be a single-shot laser or a multi-shots laser. In an embodiment, one of the semiconductor devices 1 or a specific position of the adhesion layers 32 may be irradiated by one or more shots of laser during one irradiation process. In another embodiment, multiple places of the semiconductor devices 1 or of the adhesion layers 32 may be irradiated by one or more shots of laser, respectively, during one irradiation process. As shown in FIG. 6C, the adhesion layer 32 irradiated by the laser energy L1 may reduce the adhesion between the semiconductor device 1 and the adhesion layer 32, or cause the downward movement force of the semiconductor device 1 to be greater than the adhesion of the adhesive layer 3 to the semiconductor device 1, so that the semiconductor device 1 drops to the target substrate 50 from the carrier 30. The transferred semiconductor devices 1 are disposed on the target substrate 50 with the conductive bump 2 being away from the substrate 50. In another embodiment, in the step of FIG. 6B, the semiconductor devices 1 may directly contact the target substrate 50 first, and then, be irradiated by the laser energy L1, so that the semiconductor devices 1 may align to the target substrate 50 more precisely. After the step of FIG. 6C, a removal step may be optionally applied to the semiconductor devices 1 to remove the remaining adhesion layer 32 on the semiconductor devices 1. The removal step may include a dry etch or a wet etch, and the dry etch may be an oxygen plasma etching process. In FIGS. 6A-6C, the connection mode of the semiconductor devices 1 and the carrier 30 is not limited to the form shown in FIG. 4A, and may also be the form shown in FIGS. 4D and 4E.

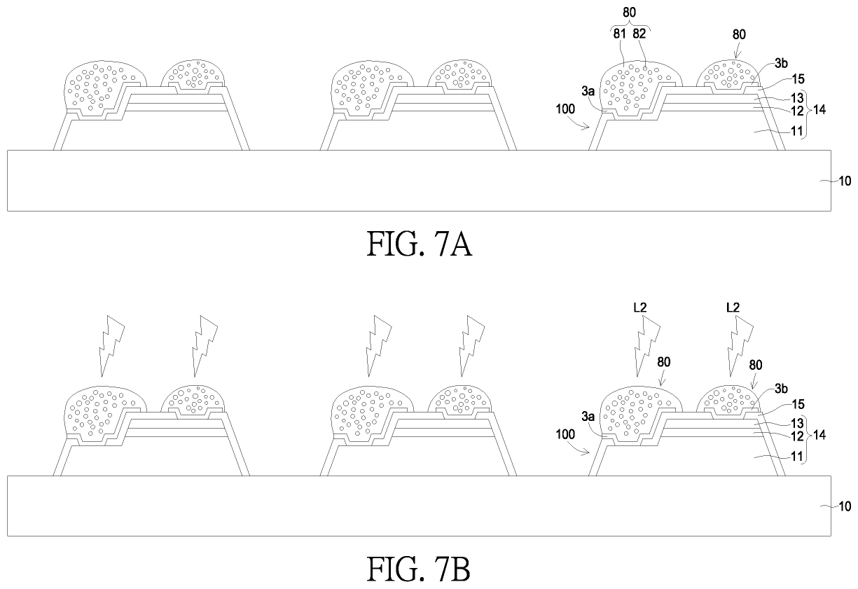

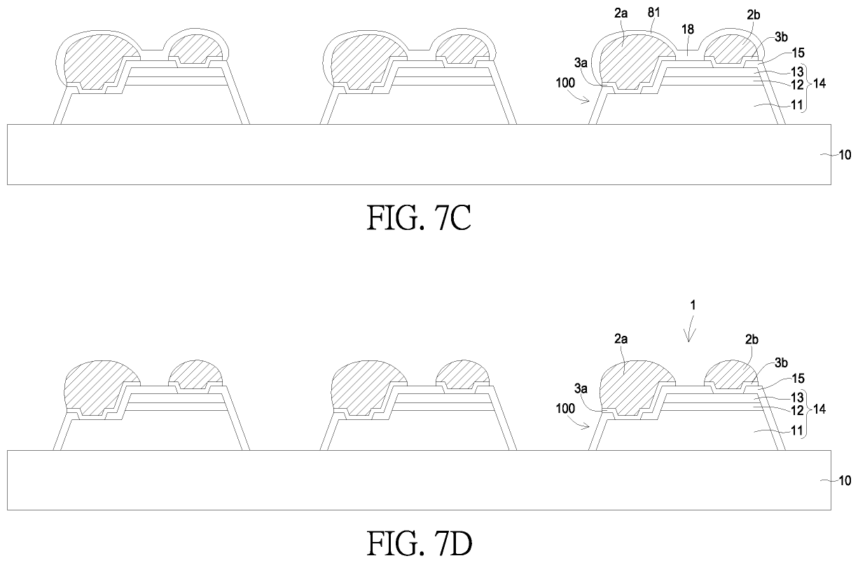

FIGS. 7A-7D are schematic views of steps for forming a semiconductor device 1 in accordance with an embodiment of the present disclosure. As shown in FIG. 7A, a plurality of semiconductor units 100 is disposed on a substrate 10. The semiconductor unit 100 includes a semiconductor stack 14, a protective layer 15, a first electrode 3a, and a second electrode 3b. The plurality of semiconductor units 100 is disposed on the substrate 10 with the first electrodes 3a and the second electrodes 3b being away from the substrate 10. The first electrode 3a and the second electrode 3b have recesses respectively. For the structures of the first electrode 3a and the second electrode 3b, references can be made to the aforementioned relevant paragraphs. Then, for each of the plurality of semiconductor units 100, two lumps of glue material 80 separated from each other are formed over the first electrode 3a and the second electrode 3b, respectively. The glue material 80 includes resin 81 and a plurality of conductive particles 82 distributed in the resin 81. In an embodiment, the glue material 80 may be formed by printing, coating, spraying, or dispensing. The printing may include aerosol jet printing or ink-jet printing. The material of the resin 81 includes thermosetting plastics and a soldering flux. The thermosetting plastics may be epoxy, silicone, polymethylmethacrylate (PMMA), or episulfide. The melting point of the conductive particle 82 is lower than the solid point of the resin 81. In an embodiment, the material of the conductive particle 82 may be gold, silver, or copper. In another embodiment, the material of the conductive particle 82 may be a low melting point metal or a low liquidus melting point alloy. In an embodiment, the melting point of the low melting point metal or the liquidus temperature of the low liquidus melting point alloy is lower than 210° C. In another embodiment, the melting point of the low melting point metal or the liquidus temperature of the low liquidus melting point alloy is lower than 170° C. The material of the low liquidus melting point alloy may be a tin alloy, such as a tin-indium alloy and tin-bismuth alloy.

As shown in FIG. 7B, a laser energy L2 is used to irradiate the glue material 80 or neighboring regions thereof to heat the glue material 80. The laser energy L2 may include UV laser beam, visible light laser beam, or IR laser beam. In an embodiment, the laser energy L2 is an IR pulse mode laser beam with wavelength of 750-2,000 nm, spot size of 0.004-0.002 cm², beam diameter of 100-500 μm, pulse width (duration) of less than 20 ms, frequency of 500-4000 Hz, duty cycle of 1%-10%, laser power of 100 W, and laser energy of 595˜850 J/cm². As shown in FIG. 7C, during the heating process, the conductive particles 82 gather on the first electrode 3a and the second electrode 3b to form the first conductive bump 2a and the second conductive bump 2b, wherein the first conductive bump 2a and the second conductive bump 2b are convex and have arc outer surfaces. The resin 81 moves over the first conductive bump 2a, second conductive bump 2b, and the region 18 between the first electrode 3a and the second electrode 3b. After the heating process, the first conductive bump 2a and the second conductive bump 2b are cured, and the resin 81 covering the first conductive bump 2a and the second conductive bump 2b is also heated but not completely cured, so the resin 81 is in a liquid or semi-liquid state. Then, as shown in FIG. 7D, a cleaning step is performed to remove the uncured resin 81 so that the first conductive bump 2a and the second conductive bump 2b are exposed to the external environment for contacting the carrier plate in subsequent transferring process. The cleaning process may be performed with a solvent, and the solvent may include N-methylpyrrolidinone (NMP), methyl ethyl ketone (MEK), acetone (ACE), or isopropyl alcohol.

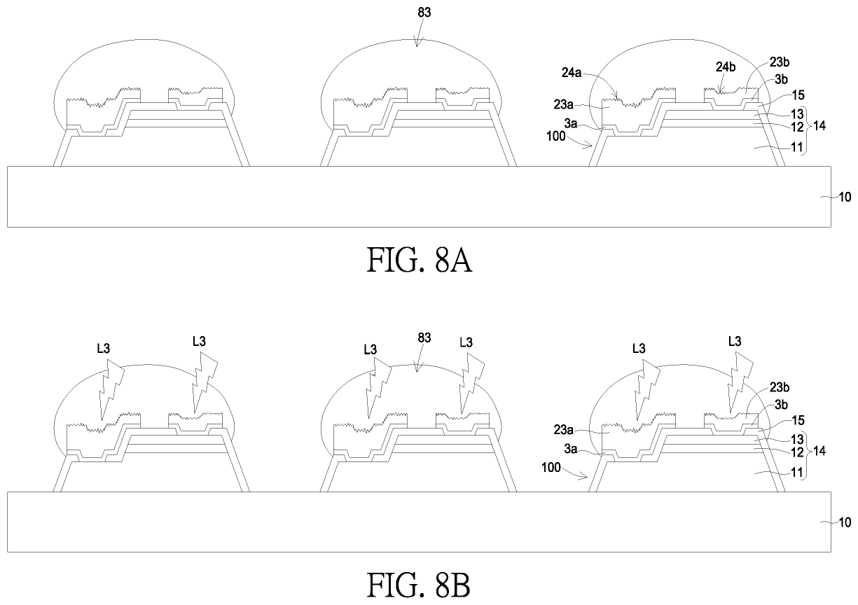

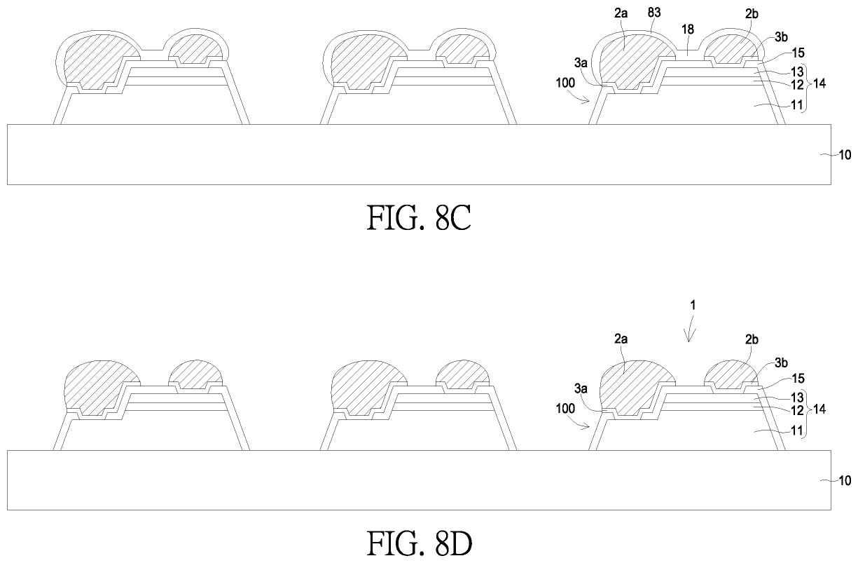

FIGS. 8A-8D are schematic views of steps for forming the semiconductor device 1 in accordance with another embodiment of the present disclosure. As shown in FIG. 8A, a plurality of semiconductor units 100 is disposed over a substrate 10. The semiconductor unit 100 includes a semiconductor stack 14, a protective layer 15 a first electrode 3a, and a second electrode 3b. The plurality of semiconductor units 100 is disposed over the substrate 10 with the first electrode 3a and the second electrode 3b being away from the substrate 10. The first electrode 3a and the second electrode 3b have recesses respectively. For the structures of the first electrode 3a and the second electrode 3b, references can be made to the aforementioned relevant paragraphs. A first bonding pad 23a and a second bonding pad 23b are formed respectively on the first electrode 3a and the second electrode 3b by using a method of electroplating, chemical plating, or evaporation deposition. The upper surface 24a of the first bonding pad 23a and the upper surface 24b of the second bonding pad 23b are substantially conformal with the upper surface of the first electrode 3a and the second electrode 3b (i.e., the profiles of the both are similar), and have recesses and/or rough texture. A single lump of the glue materials 83 is formed over the semiconductor unit 100, first bonding pad 23a, and the second bonding pad 23b of each of the plurality of semiconductor units 100. The glue material 83 only includes resin in this example. In another embodiment, the glue material 83 includes resin and lower concentration conductive particles (compared to the conductive particles of FIG. 7A). In an embodiment, the forming of the glue material 80 may be printing, coating, spraying, or dispensing. The printing may include aerosol jet printing or ink-jet printing. For the material of the first bonding pad 23a and the second bonding pad 23b, references can be made to the aforementioned relevant paragraphs of the conductive bump 2a, 2b. For the material of the resin, reference can be made to the aforementioned relevant paragraphs.

As shown in FIG. 8B, the first bonding pad 23a and the second bonding pad 23b are irradiated with a laser energy L3 to heat the glue materials 83, first bonding pad 23a, and the second bonding pad 23b. The laser energy L3 may include UV laser beam, visible light laser beam, or IR laser beam. In an embodiment, the laser energy L3 is IR laser beam with the wavelength of 750-2,000 nm. As shown in FIG. 8C, during the heating process, the first bonding pad 23a and the second bonding pad 23b are heated to melt in the glue material 83 and gather on the first electrode 3a and the second electrode 3b (if the resin includes conductive particles, some or all of the heated conductive particles may also move toward the first electrode 3a and the second electrode 3b) to form a first conductive bump 2a and the second conductive bump 2b, wherein the first conductive bump 2a and the second conductive bump 2b are convex and have arc outer surfaces. The glue material 83 moves over the first conductive bump 2a, the second conductive bump 2b, and the region 18 between the first electrode 3a and the second electrode 3b. After the heating process, the first conductive bump 2a and the second conductive bump 2b are cured, and the glue material 83 (or resin) covering thereon is heated but not completely cured, so the resin 81 is in a liquid or semi-liquid state. Then, as shown in FIG. 8D, A cleaning process is performed to remove the uncured glue material 83 (or resin) so that the first conductive bump 2a and the second conductive bump 2b are exposed to external environment for contacting the carrier plate in subsequent transferring process. For the cleaning process, reference can be made to the aforementioned relevant paragraphs of FIG. 7D.

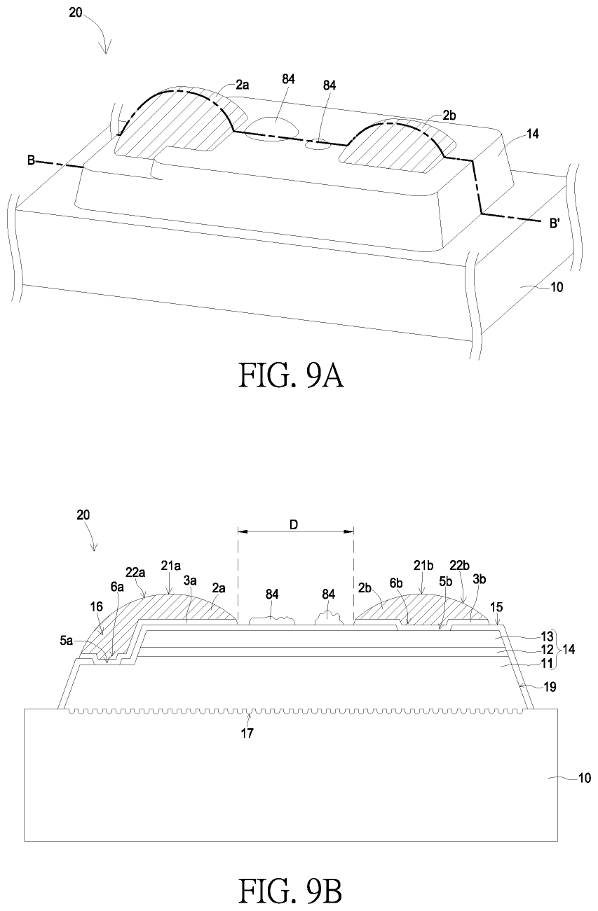

In another embodiment, during the cleaning process of FIGS. 7D and 8D, if the glue material between the conductive bumps 2a and 2b is not cleaned completely and remained on the semiconductor device 100, the maximum level height of the remaining glue material is preferably not higher than the conductive bumps 2a and 2b for preventing from affecting the subsequent transfer and die-bonding process. FIG. 9A is a three-dimensional view of a semiconductor device 20 in accordance with another embodiment of the present disclosure. FIG. 9B is a cross-sectional view taken along the line B-B′ of the semiconductor device 20 of FIG. 9A. Referring to FIG. 9A, the upper side of the semiconductor device 20 has a first conductive bump 2a and a second conductive bump 2b separated from each other. Between the first conductive bump 2a and the second conductive bump 2b, at least one lump of remaining glue material 84 is covered on the semiconductor device 20. In the top view, two lumps of remaining glue material 84 have irregular shapes and different areas. Referring to FIG. 9B, the semiconductor device 20 has a semiconductor stack 14, a protective layer 15, a first electrode 3a, a second electrode 3b, a first conductive bump 2a, and a second conductive bump 2b. The outermost side 19 of the semiconductor stack 14 is an inclined plane that is inclined with respect to the substrate 10. The semiconductor stack 14 includes a first semiconductor layer 11, an active layer 12, and a second semiconductor layer 13. The remaining glue material 84 is on the protective layer 15 between the first conductive bump 2a and the second conductive bump 2b. The uppermost surface of the remaining glue material 84 is not higher than the maximum level height of the first conductive bump 2a and the second conductive bump 2b, and has a rough outer surface. Since the height of the remaining glue material 84 is not beyond that of the conductive bump 2a and 2b, the subsequent transferring and die-bonding process may not be affected.

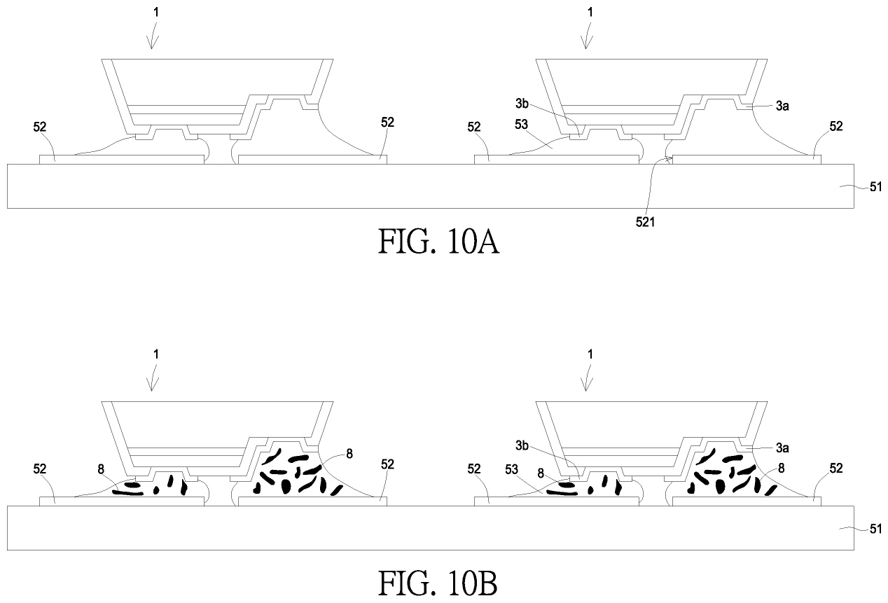

FIG. 10A is a semiconductor device 1 bonded on the target substrate 51 in accordance with an embodiment of the present disclosure. The target substrate 51 may be a circuit board of a display, a TFT substrate, a substrate having redistribution layer (RDL), or a sub-mount substrate of a package. The target substrate 51 has a plurality of conductive connecting pads 52 thereon. The semiconductor device 1 may be any of the structure mentioned previously. The conductive bumps are heated to melt and cured to form bonding layers 53 for connecting the semiconductor device 1 and the conductive connecting pads 52. The semiconductor device 1 may receive an electrical and/or driving signal through the conductive connecting pads 52 and the bonding layers 53. The bonding layer 53 may selectively cover the lateral surface 521 of the conductive connecting pad 52. During the process of heating the conductive bump to form the bonding layer 53, discrete metal particles may appear in the bonding layer 53 due to the adjustment of the process parameters, such as heating temperature, and heating time. FIG. 10B is a schematic view of a semiconductor device 1 bonded on the target substrate 51 in accordance with another embodiment of the present disclosure. After the bonding layer 53 is cured, irregular particles 8 appear in the bonding layer 53. In other words, the bonding layer 53 has discretely distributed and irregularly shaped particles 8 distributed therein, wherein the material of the particles 8 is different from the material of the bonding layer 53, but partially the same as the material of the electrode 3a, 3b and/or the conductive connecting pad 52 of the semiconductor device 1, such as gold, platinum, and alloys thereof. In an embodiment, a laser energy may be used in the heating-to-cure method, and the laser energy may include UV laser beam, visible light laser beam, and IR laser beam. In an embodiment, the wavelength of the IR laser beam is 750-2,000 nm.

In another embodiment, the compositions of the conductive bumps and the electrodes do not contain element gold (Au). This configuration can be applied to the semiconductor devices 1, 1′, 20 in any of the aforementioned embodiments, that is, the conductive bumps 2a, 2b and the electrodes 3a, 3b do not contain Au. If the electrodes 3a, 3b contain Au, and the conductive bumps 2a, 2b contain Sn, the gold-tin intermetallic compound (Au—Sn IMC), such as AuSn₄, is easily formed in the conductive bumps 2a, 2b after Au and Sn are heated. The melting point of Au—Sn IMC can reach 300° C. or higher, which is usually higher than the melting point of Sn in the conductive bump. The heating temperature applied to the process of bonding the semiconductor devices 1, 1′, 20 onto the target substrate 51 is usually kept under the melting point of Sn in the conductive bumps 2a, 2b to prevent the semiconductor devices 1, 1′, 20 from being damaged by being heated with unacceptable high temperature such as the melting point of Sn, 231.9° C. Therefore, if excessive Au—Sn IMC that does not melt at the processing temperature, exists during the process, the semiconductor devices 1, 1′, 20 can be hindered from being firmly bonded onto the target substrate 51. In addition, Au—Sn IMC is a brittle material, the Au—Sn IMC itself easily becomes the weak point of the structure, and reduces the reliability of the semiconductor devices or the process of manufacturing the device.

In another embodiment, the conductive bump and the electrode of the semiconductor device do not contain Au. However, the conductive connecting pad on the target substrate contain Au. Specifically, the conductive connecting pad has multi-metal layers stacked on top of each other, and the outermost layer of the multi-metal layer, which is in direct contact with the conductive bump, is a gold layer. This configuration can be applied to the semiconductor devices 1, 1′, 20 in any of the aforementioned embodiments, that is, the conductive bumps 2a, 2b and the electrodes 3a, 3b do not contain Au, however, the conductive connecting pads 52 of the target substrates 50, 51 contain a gold layer. The gold layer of the conductive connecting pad can prevent oxidation from happening to the materials underneath the gold layer, and also form IC along with another metal contained in the conductive bump, such as Sn, to create a connection layer with a higher melting point than the melting point of Sn, 231.9° C., between the conductive connecting pad and the conductive bump.

In another embodiment, the electrodes of the semiconductor device contain multi-metal layers stacked on top of each other, and the outermost layer of the multi-metal layers which is in direct contact with the conductive bump is a thin gold layer. This configuration can be applied to the semiconductor devices 1, 1′, 20 in any of the aforementioned embodiments, that is, the electrode 3a, 3b contains a thin gold layer. The thin gold layer can prevent oxidation from happening to other metal layer underneath the thin gold layer, and is not too thick to generate too much Au—Sn IMC along with the conductive bump. Along a direction from the semiconductor device to the conductive bump, the electrode is composed of a structure such as a stack of Cr/Ni/Au, Cr/Ni/Pt/Au, Cr/Al/Ni/Pt/Au, Cr/Ti/Al/Ni/Pt/Au, or Cr/Al/Cr/Pt/Au. In a cross-sectional view of the semiconductor device (as shown in FIG. 2B, FIG. 2C, FIG. 2E, FIG. 9B), to prevent oxidation, the thin gold layer has a thickness of greater than 50 angstroms (Å), for example, 250 Å, 125 Å; and to prevent the generation of excessive Au—Sn IMC, the thin gold layer has a thickness of less than 500 Å. If the electrode has a total thickness of 3000 Å ˜ 5000 Å, the thickness ratio of the thin gold layer to the electrode is 0.01˜ 0.16, for example, 0.04, 0.07. Even if the thin gold layer produces Au—Sn IMC along with Sn, such Au—Sn IMC is usually thinner and does not completely cover the electrode. For example, the thinner Au—Sn IMC has a thickness smaller than 2000 Å, is loosely or discontinuously distributed at an interface of the electrode and the conductive bump, and does not hinder the semiconductor device from being firmly bonded onto the target substrate. In a case, notwithstanding the thin gold layer is used, Au can still be found to be loosely distributed in an area of the conductive bump far away from the corresponding electrode.

The aforementioned embodiments are only for illustrating the technical ideas and features of the present disclosure, and their purpose is to enable those skilled in the art to understand the contents of the present disclosure and implement them accordingly, instead of limiting the patent scope of the present disclosure. All equivalent changes or modifications made according to the spirit disclosed in the present disclosure should be covered by the patent scope of the present disclosure.

What is claimed is:

1. A semiconductor device, comprising:
a semiconductor stack;
a protective layer on the semiconductor stack and having an uppermost surface;
a first electrode on the semiconductor stack and electrically connected to the semiconductor stack, wherein the first electrode comprising a first upper surface; and
a first conductive bump on the first electrode and having a first convex outermost surface, a top, and a maximum width, wherein a thickness of the first conductive bump is defined from the top to the uppermost surface, and a ratio of the thickness to the maximum width is from 0.1 to 0.4, and the first electrode is devoid of gold.

2. The semiconductor device as claimed in claim 1, further comprising a plurality of particles discretely distributed within the first conductive bump.

3. The semiconductor device as claimed in claim 2, wherein a material of the plurality of particles is the same as a material of the first electrode, and is different from a material of the first conductive bump.

4. The semiconductor device as claimed in claim 1, wherein the first electrode has a concave, and the first conductive bump fills the concave.

5. The semiconductor device as claimed in claim 1, wherein the first conductive bump is substantially a rectangle in a top view.

6. The semiconductor device as claimed in claim 1, wherein, in a cross-sectional view of the first conductive bump, the first convex outermost surface comprises a first curve with a first endpoint in contact with the first upper surface of the first electrode, and a first tangent line of the first curve at the first endpoint form an angle θ1 in a range of 70° and 90° with respect to the upper surface of the first electrode.

7. The semiconductor device as claimed in claim 6, further comprising a second electrode having a second upper surface on the semiconductor stack, and a second conductive bump on the second electrode, wherein in the cross-sectional view, the second conductive bump has a second convex outermost surface comprising a second curve with a second endpoint in contact with the second upper surface of the second electrode, and a second tangent line of the second curve at the second endpoint form an angle θ2 smaller than θ1 with respect to the second upper surface of the second electrode.

8. The semiconductor device as claimed in claim 1, further comprising a glue material on the protective layer and separated from the first conductive bump.

9. The semiconductor device as claimed in claim 8, wherein a height of the glue material is smaller than a height of the first conductive bump.

10. A semiconductor device, comprising:
a semiconductor stack;
an electrode on the semiconductor stack and electrically connected to the semiconductor stack; and
a conductive bump on the first electrode and having a first outermost surface, a top, and a maximum width,
wherein the conductive bump comprises gold, and a portion at an interface of the electrode and the conductive bump is devoid of gold.

11. The semiconductor device as claimed in claim 10, wherein the conductive bump has an outermost surface, and the outermost surface is not parallel with the electrode and has a convex arc shape.

12. The semiconductor device as claimed in claim 10, wherein the electrode and the conductive bump are formed of different materials.

13. The semiconductor device as claimed in claim 10, wherein the conductive bump has a plurality of discretely distributed particles therein, and a material of the plurality of discretely distributed particles is partially the same as a material of the electrode and different from a material of the conductive bump.

14. The semiconductor device as claimed in claim 10, wherein a cross-sectional shape of the conductive bump in a direction parallel to a side length of the electrode is not equal to a cross-sectional shape of the conductive bump in a direction of a diagonal line of the electrode.

15. A light-emitting device, comprising:
a substrate comprising a plurality of conductive connecting pads;
a semiconductor device on the substrate, wherein the semiconductor device comprises:
a semiconductor stack;
a protective layer on the semiconductor stack and having an uppermost surface; and
an electrode on the semiconductor stack and electrically connected to the semiconductor stack; and
a bonding layer connecting the electrode and one of the plurality of conductive connecting pads,
wherein the electrode is devoid of gold, and
wherein the bonding layer comprise a plurality of particles, and a material of the plurality of particles is different from that of the bonding layer and the same as a material of the electrode.

16. The light-emitting device according to claim 15, wherein the plurality of particles is discretely distributed in the bonding layer.

17. The light-emitting device according to claim 15, wherein the plurality of particles comprises gold, platinum, or alloys thereof.

18. The light-emitting device according to claim 15, wherein the substrate comprises a circuit board of a display, a TFT substrate, a substrate having redistribution layer (RDL), or a sub-mount substrate of a package.

19. The light-emitting device according to claim 15, wherein the material of the plurality of particles is the same as a material of the plurality of conductive connecting pads.
